(19) United States
(12) Patent Application Publication
(10) Pub. No.: US 2024/0079329 A1
(43) Pub. Date: Mar. 7, 2024

(54) INTEGRATED CIRCUIT DEVICES INCLUDING A BACK SIDE POWER DISTRIBUTION NETWORK STRUCTURE AND METHODS OF FORMING THE SAME

(71) Applicant: Samsung Electronics Co., Ltd., Suwon-si (KR)

(72) Inventors: EUN SUNG KIM, Clifton Park, NY (US); JAE YOUNG CHOI, Hwaseong-si (KR); WONHYUK HONG, Clifton Park, NY (US); SEUNGCHAN YUN, Waterford, NY (US); JAEJIK BAEK, Watervliet, NY (US); SEUNG MIN SONG, Halfmoon, NY (US); KANG-ILL SEO, Springfield, VA (US)

(21) Appl. No.: 18/162,920

(22) Filed: Feb. 1, 2023

Related U.S. Application Data
(60) Provisional application No. 63/374,624, filed on Sep. 6, 2022.

(51) Int. Cl. H01L 23/528; H01L 21/768; H01L 21/8234; H01L 23/535

(52) U.S. Cl. CPC H01L 23/5286; H01L 21/76898; H01L 21/823475; H01L 23/535

(57) ABSTRACT

Integrated circuit devices and methods of forming the same are provided. The methods may include forming a sacrificial layer in a preliminary substrate by adding an element into the preliminary substrate, forming a transistor structure on the preliminary substrate, the transistor structure including a source/drain region, replacing the sacrificial layer with a power contact that comprises an upper surface contacting the source/drain region, and forming a power rail that contacts a lower surface of the power contact.

### CROSS-REFERENCE TO RELATED APPLICATION

This application claims priority to U.S. Provisional Application Ser. No. 63/374,624 entitled PATTERNING METHOD OF BURIED CONTACT IN BSPDN USING DOPED PLACEHOLDER, filed in the USPTO on Sep. 6, 2022, the disclosure of which is hereby incorporated by reference herein in its entirety.

### BACKGROUND

The present disclosure generally relates to the field of integrated circuit devices and, more particularly, to integrated circuit devices including a backside power distribution network (BSPDN) structure.

Various structures of an integrated circuit device and methods of forming the same have been proposed to increase the integration density of the integrated circuit device. Specifically, an integrated circuit device including elements formed in a substrate or on a backside of the substrate has been proposed to simplify the middle-of-line (MOL) portion and/or the back-end-of-line (BEOL) portion of device fabrication.

### SUMMARY

A method of forming an integrated circuit devices according to some embodiments may include forming a sacrificial layer in a preliminary substrate by adding an element into the preliminary substrate; forming a transistor structure on the preliminary substrate, the transistor structure including a source/drain region; replacing the sacrificial layer with a power contact that comprises an upper surface contacting the source/drain region; and forming a power rail that contacts a lower surface of the power contact.

A method of forming an integrated circuit devices according to some embodiments may include converting a portion of a preliminary substrate to a sacrificial layer including an element; forming a transistor structure on the preliminary substrate, the transistor structure including a source/drain region; replacing the sacrificial layer with a power contact that comprises an upper surface contacting the source/drain region; and forming a power rail that contacts a lower surface of the power contact.

An integrated circuit devices according to some embodiments may include a transistor structure on a substrate, the transistor structure including a source/drain region; a power rail that is spaced apart from the source/drain region in a first direction; and a power contact. The source/drain region may overlap the power contact in the first direction, and the power contact may be electrically connected to the source/drain region and the power rail, and the power contact may include opposing side surfaces outwardly curved.

### BRIEF DESCRIPTION OF THE DRAWINGS

FIGS. 1 through 5 respectively are cross-sectional views of integrated circuit devices according to some embodiments.

FIG. 6 is a flow chart of a method of forming an integrated circuit device according to some embodiments.

FIGS. 7 through 15 are cross-sectional views illustrating a method of forming an integrated circuit device according to some embodiments.

FIGS. 16 and 17 are cross-sectional views illustrating a method of forming an integrated circuit device according to some embodiments.

### DETAILED DESCRIPTION

According to some embodiments, an integrated circuit device may be formed by forming a placeholder (also referred to as a sacrificial layer) in a substrate by adding an element into a portion of the substrate and then replacing the placeholder with a power contact. The placeholder may have a flat upper surface, as the placeholder is formed by converting a portion of the substrate to the placeholder. After the power contact is formed, a BSPDN structure may be formed on the power contact. The BSPDN structure may simplify the MOL portion and/or the BEOL portion of device fabrication.

Example embodiments will be described in greater detail with reference to the attached figures.

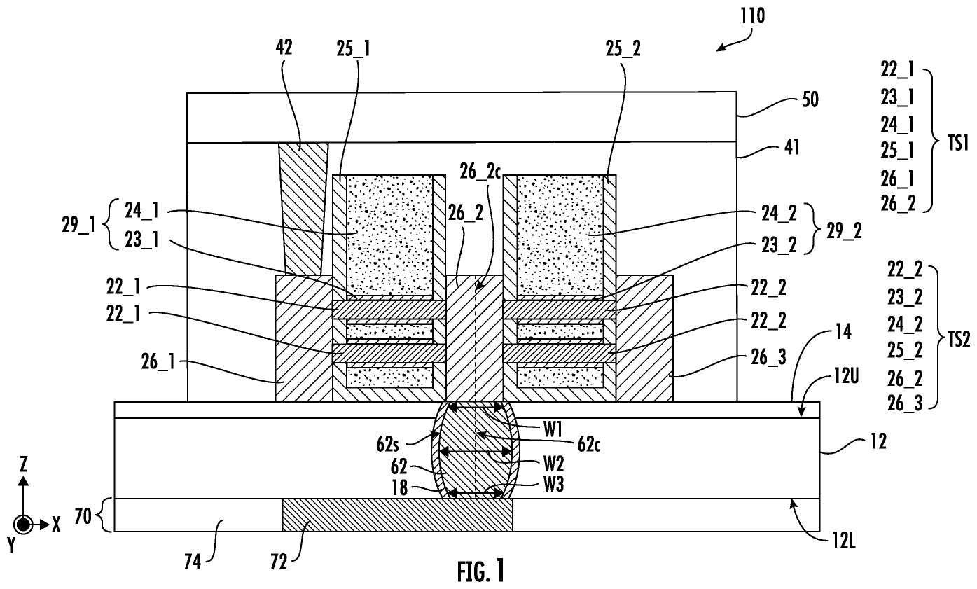

FIG. 1 is a cross-sectional view of a first integrated circuit device 110 according to some embodiments. The first integrated circuit device 110 may include a first transistor structure TS1 and a second transistor structure TS2 on a substrate 12 that includes an upper surface 12U and a lower surface 12L. The substrate 12 may be also referred to as a lower insulator. In some embodiments, the upper surface 12U of the substrate 12 may extend in a first direction X (also referred to as a first horizontal direction) and a second direction Y (also referred to as a second horizontal direction). The upper surface 12U of the substrate 12 may be parallel to the lower surface 12L of the substrate 12. Accordingly, the first direction X and the second direction Y may be parallel to the upper surface 12U and the lower surface 12L of the substrate 12. In some embodiments, the first direction X may be perpendicular to the second direction Y.

The substrate 12 may include insulating material(s), for example, silicon oxide, silicon oxynitride, silicon nitride, silicon carbonitride and/or a low-k material and may also include semiconductor material(s), for example, Si, Ge, SiGe, GaP, GaAs, SiC, SiGeC and/or InP. A thickness of the substrate 12 in a third direction Z (also referred to as a vertical direction) may be in a range of 50 nm to 100 nm. In some embodiments, the third direction Z may be perpendicular to the first direction X and the second direction Y. For example, the low-k material may include fluorine-doped silicon oxide, organosilicate glass, carbon-doped oxide, porous silicon dioxide, porous organosilicate glass, spin-on organic polymeric dielectrics and/or spin-on silicon based polymeric dielectric.

The first integrated circuit device 110 may further include a first interlayer 14 that may be provided on the upper surface 12U of the substrate 12. In some embodiments, the first interlayer 14 may extend between the substrate 12 and the first and second transistor structures TS1 and TS2 and may contact the upper surface 12U of the substrate 12. For example, the first interlayer 14 may include insulating material(s) (e.g., silicon oxide, silicon oxynitride, silicon nitride, silicon carbonitride and/or a low-k material).

The first transistor structure TS1 may include a first channel region 22_1. In some embodiments, the first transistor structure TS1 may include multiple first channel regions 22_1 stacked in the third direction Z, and the first channel regions 22_1 may be spaced apart from each other in the third direction Z, as illustrated in FIG. 1. The first transistor structure TS1 may also include a first gate structure 29_1 that may include a first gate insulator 23_1 and a first gate electrode 24_1. The first channel region 22_1 may extend through the first gate electrode 24_1 in the first direction X, and the first gate insulator 23_1 may be provided between the first gate electrode 24_1 and the first channel region 22_1. For example, the first gate insulator 23_1 may be provided on upper and lower surfaces of the first channel region 22_1. The first gate insulator 23_1 may contact the first gate electrode 24_1 and the first channel region 22_1.

The second transistor structure TS2 may include a second channel region 22_2. In some embodiments, the second transistor structure TS2 may include multiple second channel regions 22_2 stacked in the third direction Z, and the second channel regions 22_2 may be spaced apart from each other in the third direction Z, as illustrated in FIG. 1. The second transistor structure TS2 may also include a second gate structure 29_2 that may include a second gate insulator 23_2 and a second gate electrode 24_2. The second channel region 22_2 may extend through the second gate electrode 24_2 in the first direction X, and the second gate insulator 23_2 may be provided between the second gate electrode 24_2 and the second channel region 22_2. The second gate insulator 23_2 may contact the second gate electrode 24_2 and the second channel region 22_2.

Further, the first transistor structure TS1 may include first and second source/drain regions 26_1 and 26_2 that may be spaced apart from each other in the first direction X, and the first gate structure 29_1 may be provided between the first and second source/drain regions 26_1 and 26_2. The first and second source/drain regions 26_1 and 26_2 may contact opposing side surfaces of the first channel region 22_1, respectively, as illustrated in FIG. 1. The second transistor structure TS2 may include the second source/drain region 26_2 and a third source/drain region 26_3 that may be spaced apart from each other in the first direction X, and the second gate structure 29_2 may be provided between the second and third source/drain regions 26_2 and 26_3. The second and third source/drain regions 26_2 and 26_3 may contact opposing side surfaces of the second channel region 22_2, respectively, as illustrated in FIG. 1. The second source/drain region 26_2 may also be referred to as a common source/drain region, as the second source/drain region 26_2 is shared by the first and second transistor structures TS1 and TS2. Although not illustrated, an additional gate structure may be provided adjacent to the first source/drain region 26_1 or the third source/drain region 26_3. In some embodiments, the first source/drain region 26_1 may be between the first gate structure 29_1 and the additional gate structure. In some other embodiments, the third source/drain region 26_3 may be between the second gate structure 29_2 and the additional gate structure.

Each of the first and second channel regions 22_1 and 22_2 may include semiconductor material(s) (e.g., Si, Ge, SiGe, GaP, GaAs, SiC, SiGeC and/or InP). In some embodiments, the first and second channel regions 22_1 and 22_2 may include the same material(s). In some embodiments, each of the first and second channel regions 22_1 and 22_2 may be a nanosheet that may have a thickness in a range of from 1 nm to 100 nm in the third direction Z or may be a nanowire that may have a circular cross-section with a diameter in a range of from 1 nm to 100 nm.

Each of the first and second gate insulators 23_1 and 23_2 may include a single layer or multiple layers (e.g., a silicon oxide layer and/or a high-k material layer). For example, the high-k material layer may include Al₂O₃, HfO₂, ZrO₂, HfZrO₄, TiO₂, Sc₂O₃Y₂O₃, La₂O₃, Lu₂O₃, Nb₂O₅ and/or Ta₂O₅. In some embodiments, each of the first and second gate insulators 23_1 and 23_2 may include the same material(s).

Each of the first and second gate electrodes 24_1 and 24_2 may include a single layer or multiple layers. In some embodiments, each of the first and second gate electrodes 24_1 and 24_2 may include a metallic layer that includes, for example, tungsten (W), aluminum (Al), copper (Cu), molybdenum (Mo) and/or ruthenium (Ru) and may additionally include work function layer(s) (e.g., a TiN layer, a TaN layer, a TiAl layer, a TiC layer, a TiAlC layer, a TiAlN layer and/or a WN layer). In some embodiments, the first and second gate electrodes 24_1 and 24_2 may include the same material(s). The work function layer(s) may be provided between the metallic layer and the gate insulator (i.e., one of the first and second gate insulators 23_1 and 23_2). In some embodiments, the work function layer(s) may separate the metallic layer from the gate insulator.

Each of the first, second and third source/drain regions 26_1, 26_2 and 26_3 may include a semiconductor layer (e.g., a silicon layer and/or a silicon germanium layer) and may additionally include dopants in the semiconductor layer. In some embodiments, each of the first, second and third source/drain regions 26_1, 26_2 and 26_3 may include a metal layer that includes, for example, W, Al, Cu, Mo and/or Ru.

The first and second transistor structures TS1 and TS2 may also respectively include first and second insulating spacers 25_1 and 25_2 (also referred to as gate spacers or inner gate spacers). The first insulating spacer 25_1 may be provided between the first gate electrode 24_1 and the first and second source/drain regions 26_1 and 26_2 and/or may be provided between the first gate electrode 24_1 and the first interlayer 14. In some embodiments, opposing surfaces of the first insulating spacer 25_1 may respectively contact the first gate electrode 24_1 and one of the first and second source/drain regions 26_1 and 26_2 and may respectively contact the first gate electrode 24_1 and the first interlayer 14, as illustrated in FIG. 1. The first channel region 22_1 may extend through the first insulating spacer 25_1 in the first direction X, as illustrated in FIG. 1.

The second insulating spacer 25_2 may be provided between the second gate electrode 24_2 and the second and third source/drain regions 26_2 and 26_3 and/or may be provided between the second gate electrode 24_2 and the first interlayer 14. In some embodiments, opposing surfaces of the second insulating spacer 25_2 may respectively contact the second gate electrode 24_2 and one of the second and third source/drain regions 26_2 and 26_3 and may respectively contact the second gate electrode 24_2 and the first interlayer 14, as illustrated in FIG. 1. The second channel region 22_2 may extend through the second insulating spacer 25_2 in the first direction X, as illustrated in FIG. 1. Each of the first and second insulating spacers 25_1 and 25_2 may include, for example, silicon oxide, silicon oxynitride, silicon nitride, silicon carbonitride and/or a low-k material.

A second interlayer 41 may be provided on the first interlayer 14, and the first and second transistor structures TS1 and TS2 may be provided in the second interlayer 41. Although FIG. 1 illustrates the second interlayer 41 as a single layer, in some embodiments, the second interlayer 41 may include multiple layers.

A source/drain contact 42 may be provided in the second interlayer 41 on the first source/drain region 26_1. The source/drain contact 42 may contact an upper surface of the first source/drain region 26_1. The source/drain contact 42 may electrically connect the first source/drain region 26_1 to a conductive element (e.g., a conductive wire or a conductive via plug) of a BEOL structure 50 that is formed through the BEOL portion of device fabrication. As used herein, “a lower surface” refers to a surface facing the substrate 12, and “an upper surface” refers to a surface opposite the lower surface. Further, as used herein, “a lower portion” refers to a portion that is closer than “an upper portion” to the substrate 12 and thus is between the upper portion and the substrate 12.

The BEOL structure 50 may include a BEOL insulating layer, conductive wires (e.g., metal wires) that are provided in the BEOL insulating layer and are stacked in the third direction Z, and conductive via plugs (e.g., metal via plugs), each of which may electrically connect two conductive wires that are spaced apart from each other in the third direction Z.

Each of the first and second interlayers 14 and 41 and the BEOL insulating layer may include, for example, silicon oxide, silicon oxynitride, silicon nitride, silicon carbonitride and/or a low-k material.

The first integrated circuit device 110 may further include a power contact 62 and a B SPDN structure 70. The power contact 62 may include an upper portion in the first interlayer 14 and a lower portion in the substrate 12. In some embodiments, the power contact 62 may extend through the first interlayer 14 and the substrate 12 in the third direction Z, and the power contact 62 (e.g., an upper surface of the power contact 62) may contact the second source/drain region 26_2 (e.g., a lower surface of the second source/drain region 26_2), as illustrated in FIG. 1.

Referring to FIG. 1, the power contact 62 may include opposing side surfaces 62s which may be outwardly curved (e.g., curved toward the substrate 12). The side surfaces 62s may be convex toward the substrate 12. The power contact 62 may include a first portion that the first channel region 22_1 overlaps in the third direction Z and a second portion that the second channel region 22_2 overlaps in the third direction Z. In some embodiments, the power contact 62 may include only one of the first and second portions. As used herein, “an element A overlapping an element B in a direction X” (or similar language) means that there is at least one line that extends in the direction X and intersects both the elements A and B.

The power contact 62 may include an upper surface that contacts the second source/drain region 26_2 (e.g., a lower surface of the second source/drain region 26_2) and has a first width W1 in the first direction X. The upper surface of the power contact 62 may be flat, as illustrated in FIG. 1. The power contact 62 may also include a lower surface that is opposite to and is spaced apart from the upper surface of the power contact 62 and has a third width W3 in the first direction X. The power contact 62 has a second width W2 in the first direction X around (e.g., at) a center point thereof in the third direction Z, and the second width W2 may be wider than the first width W1 and the third width W3. The first width W1 may be the same as or narrower than the third width W3. In some embodiments, a width of the power contact 62 in the first direction X may increase and then decrease as a distance from the second source/drain region 26_2 increases, as illustrated in FIG. 1. As used herein, “a center” may be interchangeable with “a center point.”

A contact spacer 18 may be provided on the opposing side surfaces 62s of the power contact 62. In some embodiments, the contact spacer 18 may have a uniform thickness along the opposing side surfaces 62s of the power contact 62, as illustrated in FIG. 1. The contact spacer 18 may contact the opposing side surfaces 62s of the power contact 62 and may separate the power contact 62 from the substrate 12. The contact spacer 18 may include, for example, SiN, SiBCN, SiOCN, SiBN, SiCN, SiO, SiON and/or a low-k material.

In some embodiments, a first center 26_2c of the second source/drain region 26_2 in the first direction X may be aligned with, in the third direction Z, a second center 62c of the power contact 62 in the first direction X, as illustrated in FIG. 1.

The power contact 62 may electrically connect the second source/drain region 26_2 to a conductive element (e.g., a conductive wire or a conductive via plug) of the BSPDN structure 70. The BSPDN structure 70 may include, for example, a power rail 72 and a backside insulator 74 in which the power rail 72 is provided. The power rail 72 may be electrically connected to a power source with a predetermined voltage (e.g., a drain voltage or a source voltage), and thus the second source/drain region 26_2 may be electrically connected to the power source through the power contact 62 and the power rail 72. In some embodiments, the power contact 62 may contact both the second source/drain region 26_2 and the power rail 72.

Although the backside insulator 74 is illustrated as a single layer, in some embodiments, the backside insulator 74 may include multiple layers stacked on the lower surface 12L of the substrate 12. Further, although the BSPDN structure 70 is illustrated as contacting the lower surface 12L of the substrate 12, in some embodiments, an intervening structure may be provided between the substrate 12 and the BSPDN structure 70 and may separate the substrate 12 from the BSPDN structure 70. Each of the power contact 62 and the power rail 72 may include, for example, metal element(s) (e.g., W, Al, Cu, Mo and/or Ru), and the backside insulator 74 may include, for example, silicon oxide, silicon oxynitride, silicon nitride, silicon carbonitride and/or a low-k material.

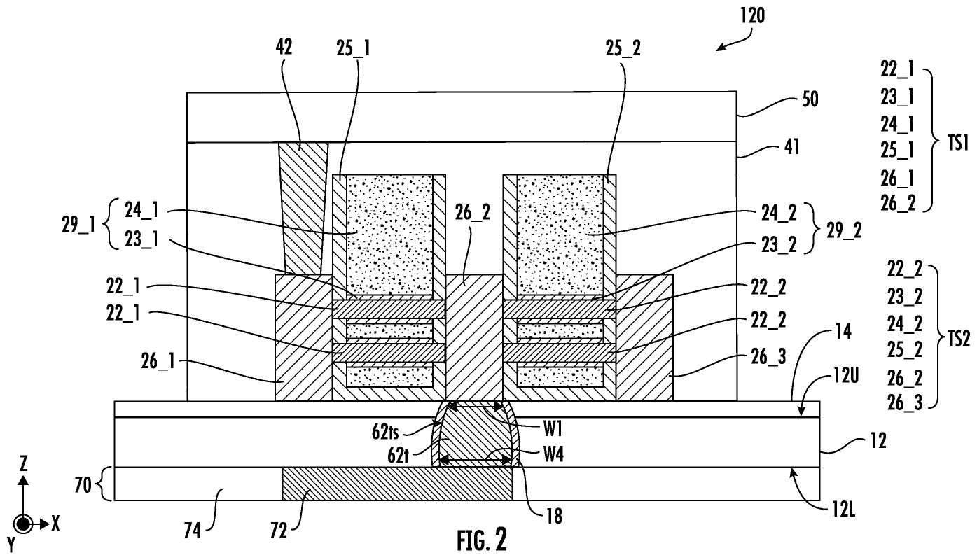

FIG. 2 is a cross-sectional view of a second integrated circuit device 120 according to some embodiments. The second integrated circuit device 120 is similar to the first integrated circuit device 110. The second integrated circuit device 120 may be different from the first integrated circuit device 110, in that a width of a power contact 62t may increase as a distance from the second source/drain region 26_2 increases. A lower surface of the power contact 62t has a fourth width W4 in the first direction X, and the fourth direction W4 may be wider than the first width W1. In some embodiments, the fourth width W4 may be a widest width of the power contact 62t, as illustrated in FIG. 2.

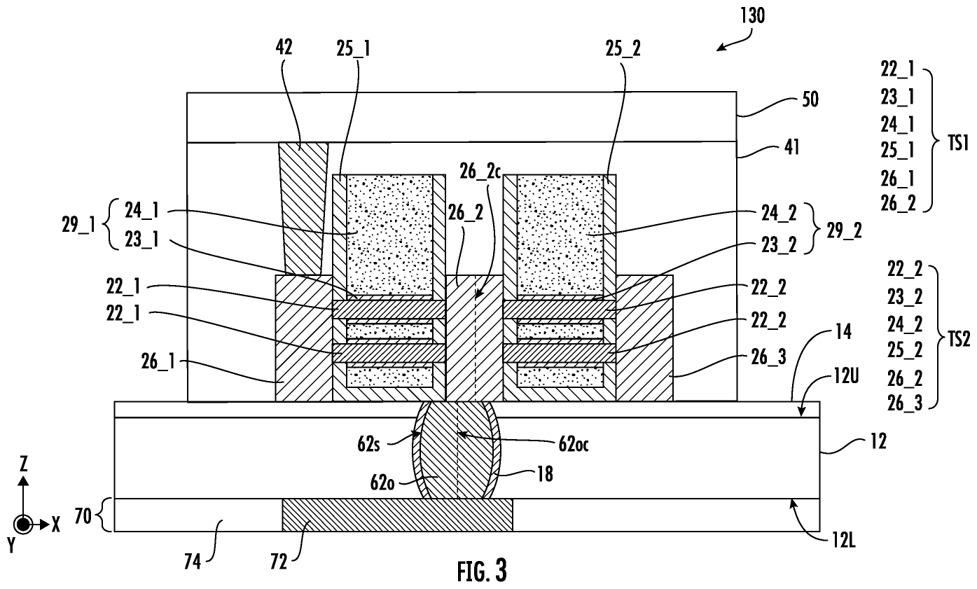

FIG. 3 is a cross-sectional view of a third integrated circuit device 130 according to some embodiments. The third integrated circuit device 130 is similar to the first integrated circuit device 110. The third integrated circuit device 130 may be different from the first integrated circuit device 110, in that the second source/drain region 26_2 may have a first center 26_2c in the first direction X, and the first center 26_2c may be offset from a second center 62oc of a power contact 62o in the first direction X, as illustrated in FIG. 3. In some embodiments, the second channel region 22_2 and a portion of the second source/drain region 26_2 may not overlap the power contact 62o in the third direction Z, as illustrated in FIG. 3 but, in some other embodiments, the second channel region 22_2 and an entirety of the second source/drain region 26_2 may overlap the power contact 62o.

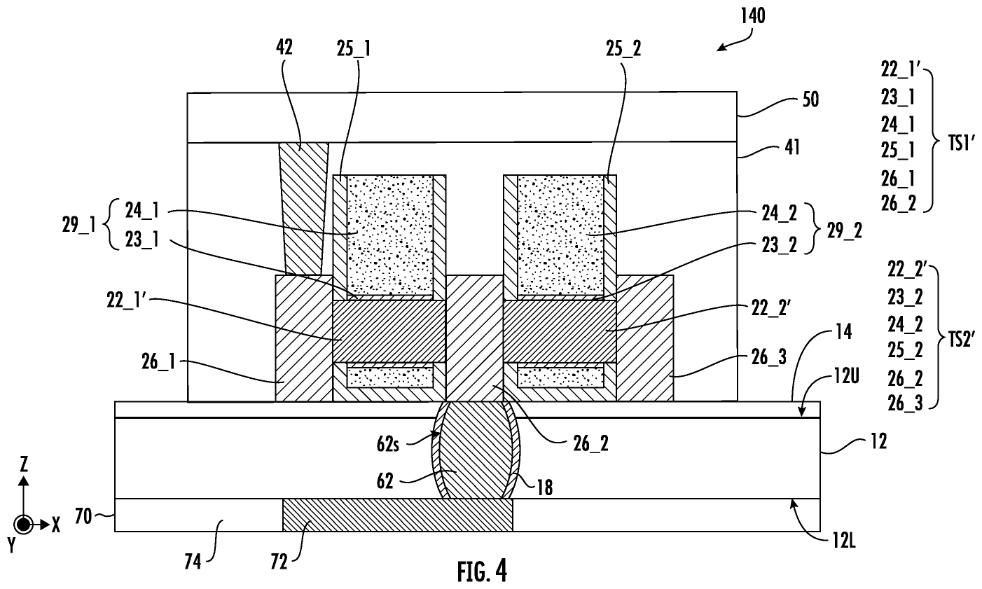

FIG. 4 is a cross-sectional view of a fourth integrated circuit device 140 according to some embodiments. The fourth integrated circuit device 140 is similar to the first integrated circuit device 110. The fourth integrated circuit device 140 may differ from the first integrated circuit device 110, in that each of the first and second transistor structures TS1 and TS2 includes a single channel region (e.g., a first channel region 22_1′ or a second channel region 22_2′). The single channel region may be referred to as a fin-shaped channel region, and each of the first and second transistor structures TS1 and TS2 may be referred to as a fin field-effect transistor (FinFET) structure.

It will be understood that the first, second and third integrated circuit devices 110, 120 and 130 may include the first and second transistor structures TS1 and TS2, each of which includes a single fin-shaped channel region and is a FinFET.

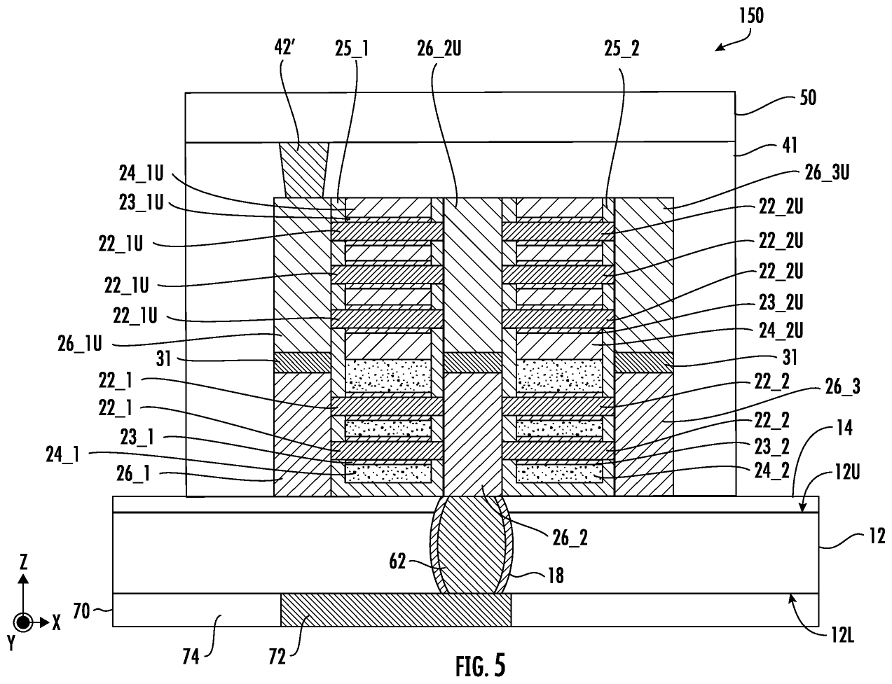

FIG. 5 is a cross-sectional view of a fifth integrated circuit device 150 according to some embodiments. The fifth integrated circuit device 150 is similar to the first integrated circuit device 110. The fifth integrated circuit device 150 may differ from the first integrated circuit device 110, in that the fifth integrated circuit device 150 further includes a first upper transistor structure and a second upper transistor structure.

The first upper transistor structure may be provided on the first transistor structure TS1, and thus the first transistor structure TS1 may be between the substrate 12 and the first upper transistor structure. The first upper transistor structure may include a first upper channel region 22_1U. In some embodiments, the first upper transistor structure may include multiple first upper channel regions 22_1U stacked in the third direction Z, and the first upper channel regions 22_1U may be spaced apart from each other in the third direction Z, as illustrated in FIG. 5. The first upper transistor structure may also include a first upper gate structure that may include a first upper gate insulator 23_1U and a first upper gate electrode 24_1U. The first upper channel region 22_1U may extend through the first upper gate electrode 24_1U in the first direction X, and the first upper gate insulator 23_1U may be provided between the first upper gate electrode 24_1U and the first upper channel region 22_1U. The first upper gate insulator 23_1U may contact first upper gate electrode 24_1U and the first upper channel region 22_1U.

The second upper transistor structure may be provided on the second transistor structure TS2, and thus the second transistor structure TS2 may be between the substrate 12 and the second upper transistor structure. The second upper transistor structure may include a second upper channel region 22_2U. In some embodiments, the second upper transistor structure may include multiple second upper channel regions 22_2U stacked in the third direction Z, and the second upper channel regions 22_2U may be spaced apart from each other in the third direction Z, as illustrated in FIG. 5. The second upper transistor structure may also include a second upper gate structure that may include a second upper gate insulator 23_2U and a second upper gate electrode 24_2U. The second upper channel region 22_2U may extend through the second upper gate electrode 24_2U in the first direction X, and the second upper gate insulator 23_2U may be provided between the second upper gate electrode 24_2U and the second upper channel region 22_2U. The second upper gate insulator 23_2U may contact the second upper gate electrode 24_2U and the second upper channel region 22_2U.

Further, the first upper transistor structure may include first and second upper source/drain regions 26_1U and 26_2U that may be spaced apart from each other in the first direction X, and the first upper gate structure may be provided between the first and second upper source/drain regions 26_1U and 26_2U. The first and second upper source/drain regions 26_1U and 26_2U may contact opposing side surfaces of the first upper channel region 22_1U, respectively, as illustrated in FIG. 5. The second upper transistor structure may include the second upper source/drain region 26_2U and a third upper source/drain region 26_3U that may be spaced apart from each other in the first direction X, and the second upper gate structure may be provided between the second and third upper source/drain regions 26_2U and 26_3U. The second and third upper source/drain regions 26_2U and 26_3U may contact opposing side surfaces of the second upper channel region 22_2U, respectively, as illustrated in FIG. 5. The second upper source/drain region 26_2U may also be referred to as a common upper source/drain region, as the second upper source/drain region 26_2U is shared by the first and second upper transistor structures.

The fifth integrated circuit device 150 may also include a third interlayer 31 that is provided between the first transistor structure TS1 and the first upper transistor structure and between the second transistor structure TS2 and the second upper transistor structure. In some embodiments, the third interlayer 31 may be between and may contact the first source/drain region 26_1 and the first upper source/drain region 26_1U, may be between and may contact the second source/drain region 26_2 and the second upper source/drain region 26_2U, and may be between and may contact the third source/drain region 26_3 and the third upper source/drain region 26_3U, as illustrated in FIG. 5. For example, the third interlayer 31 may include, for example, silicon oxide, silicon oxynitride, silicon nitride, silicon carbonitride and/or a low-k material. A source/drain contact 42′ may be provided on the first upper source/drain region 26_1U and may contact an upper surface of the first upper source/drain region 26_1U.

In some embodiments, the first transistor structure TS1 and the first upper transistor structure may have different conductivity types and may collectively form a first complementary metal-oxide-semiconductor (CMOS) structure, and the second transistor structure TS2 and the second upper transistor structure may have different conductivity types and may collectively form a second CMOS structure.

In some embodiments, each of the first transistor structure TS1, the first upper transistor structure, the second transistor structure TS2 and the second upper transistor structure may include a single fin-shaped channel region and may be a FinFET.

Each of the elements of the first and second upper transistor structures may include material(s) the same as the material(s) of a corresponding element of the first and second transistor structures TS1 and TS2. For example, the first upper source/drain region 26_1U may include material(s) the same as the material(s) of the first source/drain region 26_1, and the second upper gate electrode 24_2U may include material(s) the same as the material(s) of the second gate electrode 24_2.

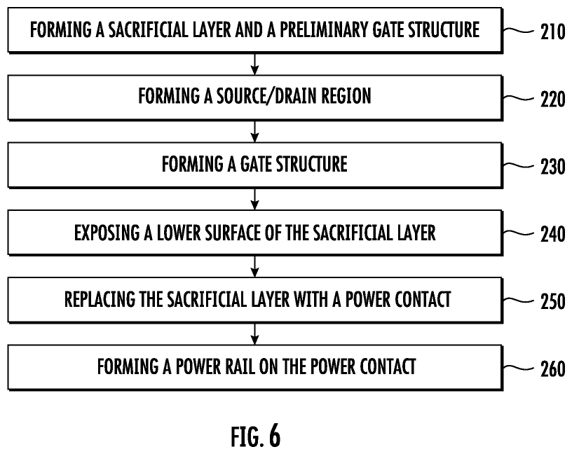

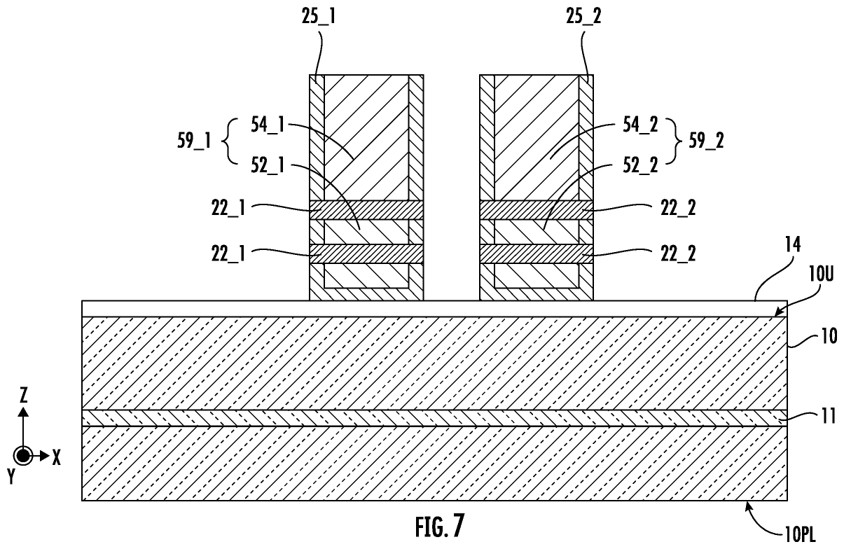

FIG. 6 is a flow chart of a method of forming the first integrated circuit device 110 according to some embodiments, and FIGS. 7 through 15 are cross-sectional views illustrating those method according to some embodiments.

Referring to FIGS. 6, 7 and 8, the method may include forming a sacrificial layer 16 and first and second preliminary gate structures 59_1 and 59_2 on a preliminary substrate 10 (e.g., an upper surface 10U of the preliminary substrate 10) (Block 210). Referring to FIG. 7, the upper surface 10U of the preliminary substrate 10 may face the first and second preliminary gate structures 59_1 and 59_2. The preliminary substrate 10 may include a preliminary lower surface 10PL that is opposite to and is spaced apart from the upper surface 10U of the preliminary substrate 10. The upper surface 10U and the preliminary lower surface 10PL of the preliminary substrate 10 may be parallel to each other. A first interlayer 14 may be formed on the upper surface 10U of the preliminary substrate 10. First channel regions 22_1 extending through the first preliminary gate structure 59_1 in the first direction X and the second channel regions 22_1 extending through the second preliminary gate structure 59_2 in the first direction X may also be formed on the preliminary substrate 10. The preliminary substrate 10 may include an etch stop layer 11 therein.

The preliminary substrate 10 may include one or more semiconductor materials, for example, Si, Ge, SiGe, GaP, GaAs, SiC, SiGeC and/or InP or may include insulating material, for example, silicon oxide, silicon oxynitride, silicon nitride, silicon carbonitride and/or a low-k material. In some embodiments, the preliminary substrate 10 may be a bulk substrate (e.g., a bulk silicon substrate) or a semiconductor on insulator (SOI) substrate. For example, the preliminary substrate 10 may be a silicon wafer or may be an insulating layer. The etch stop layer 11 may include, for example, SiN, SiBCN, SiOCN, SiBN, SiCN, SiO and/or SiON.

The first preliminary gate structure 59_1 may include a first preliminary gate layer 52_1 and a first gate mask layer 54_1, and the second preliminary gate structure 59_2 may include a second preliminary gate layer 52_2 and a second gate mask layer 54_2. Each of the first and second preliminary gate layers 52_1 and 52_2 may include material(s) having an etch selectivity with respect to the first and second channel regions 22_1 and 22_2. The first insulating spacer 25_1 may be formed a lower surface and a side surface of the first preliminary gate structure 59_1, and the second insulating spacer 25_2 may be formed a lower surface and a side surface of the second preliminary gate structure 59_2.

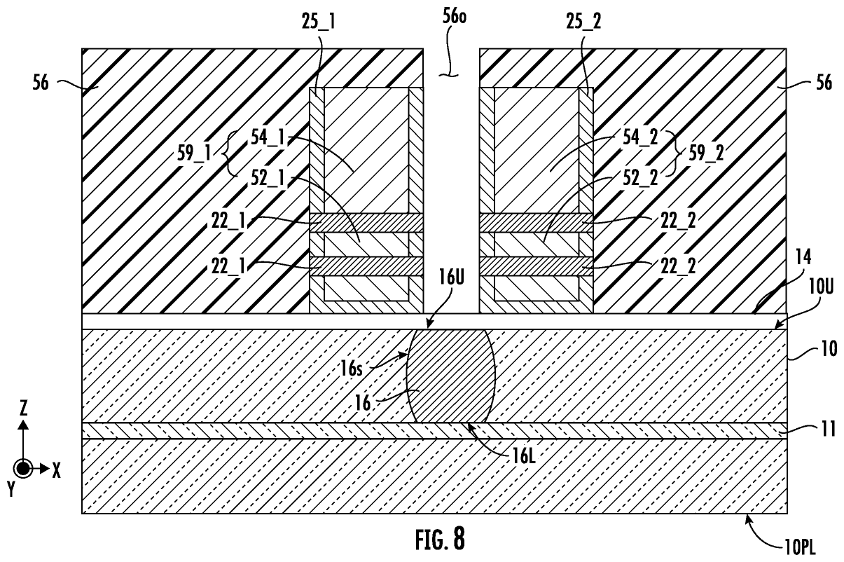

Referring to FIG. 8, a mask layer 56 may be formed on the first and second preliminary gate structures 59_1 and 59_2. The mask layer 56 may include a mask opening 56o exposing a portion of the first interlayer 14 between the first and second preliminary gate structures 59_1 and 59_2. An element (e.g., boron) may be added into a portion of the preliminary substrate 10 to convert that portion to a sacrificial layer 16 including the element. The element may be added by performing a process (e.g., an ion implantation process) on an upper surface 10U of the preliminary substrate 10 such that the element may be added into the portion of the preliminary substrate 10 through the upper surface 10U of the preliminary substrate 10. The process adding the element into the preliminary substrate 10 may be performed using the first and second preliminary gate structures 59_1 and 59_2 and the mask layer 56 as a mask. Accordingly, the sacrificial layer 16 may be self-aligned between the first and second preliminary gate structures 59_1 and 59_2. The process adding the element into the preliminary substrate 10 may use boron atoms and/or a boron trifluoride (BF 3) gas. The mask layer 56 may include an organic material (e.g., a photoresist) and/or an inorganic material (e.g., silicon oxynitride and/or a spin-on-glass material). A concentration of the element in the sacrificial layer 16 may be, for example, about 1E15atom/cm² or higher. The presence of the element in the sacrificial layer 16 gives it an etch selectivity with respect to the preliminary substrate layer 10 and a substrate 12 (described below).

In some embodiments, the sacrificial layer 16 (e.g., a lower surface 16L of the sacrificial layer 16) may contact the etch stop layer 11 and may include an upper surface 16U that is coplanar with an upper surface 10U of the preliminary substrate 10. In some embodiments, the upper surface 16U of the sacrificial layer 16 may be flat and may not include a recess or a protrusion. The sacrificial layer 16 may include opposing side surfaces 16s that are outwardly curved toward the preliminary substrate 10 and are convex.

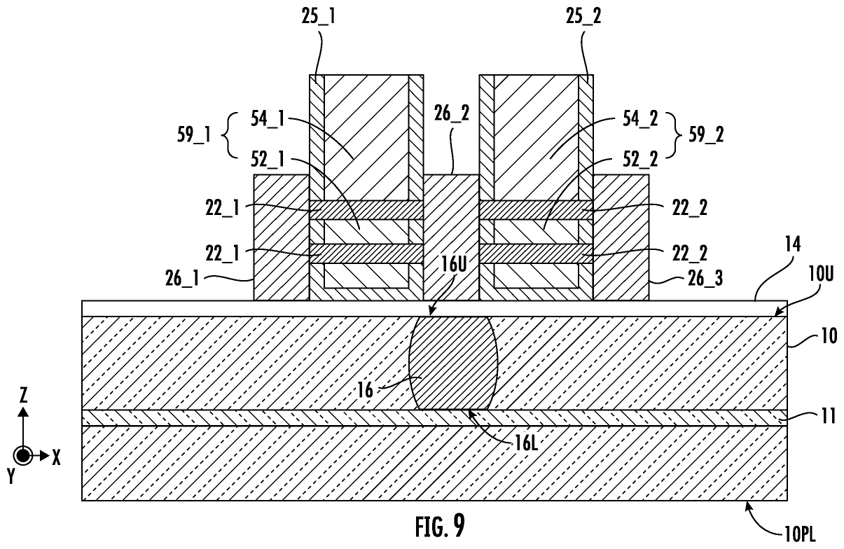

Referring to FIGS. 6 and 9, the mask layer 56 may be removed, and then a source/drain region (e.g., a second source/drain region 26_2) may be formed (Block 220). The second source/drain region 26_2 may overlap the sacrificial layer 16 in the third direction Z. In some embodiments, the source/drain region may be grown using the channel region as a seed layer through an epitaxial growth process. For example, the first and second source/drain regions 26_1 and 26_2 may be formed by performing an epitaxial growth process using the first channel region 22_1. Specifically, the first and second source/drain regions 26_1 and 26_2 may be grown from opposing side surfaces of the first channel region 22_1 through an epitaxial growth process.

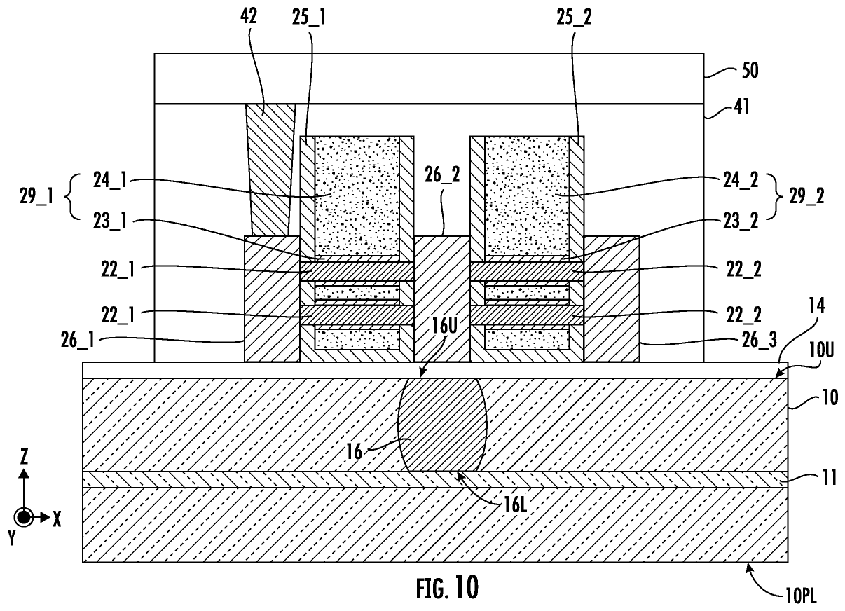

Referring to FIGS. 6 and 10, a gate structure (e.g., first and second gate structures 29_1 and 29_2) may be formed (Block 230). The first and second preliminary gate structures 59_1 and 59_2 may be replaced with the first and second gate structures 29_1 and 29_2. A second interlayer 41, a source/drain contact 42 and a BEOL structure 50 may be formed after the first and second gate structures 29_1 and 29_2 are formed.

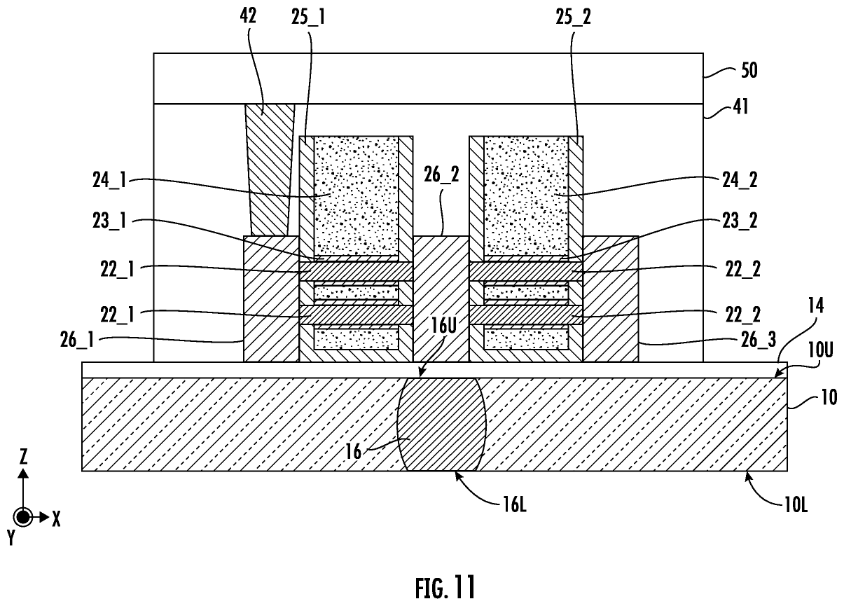

Referring to FIGS. 6 and 11, the lower surface 16L of the sacrificial layer 16 may be exposed (Block 240) by removing a lower portion of the preliminary substrate 10 and the etch stop layer 11. Process(es) (e.g., a grinding process, a wet etching process, a dry etching process and/or a Chemical Mechanical Polishing (CMP) process) may be performed on the preliminary lower surface 10PL of the preliminary substrate 10 to remove the lower portion of the preliminary substrate 10 until the etch stop layer 11 is revealed, and then the etch stop layer 11 may be further removed to reveal the lower surface 16L of the sacrificial layer 16 is exposed. After removing the lower portion of the preliminary substrate 10 and the etch stop layer 11, a lower surface 10L of the preliminary substrate 10 may be coplanar with the lower surface 16L of the sacrificial layer 16.

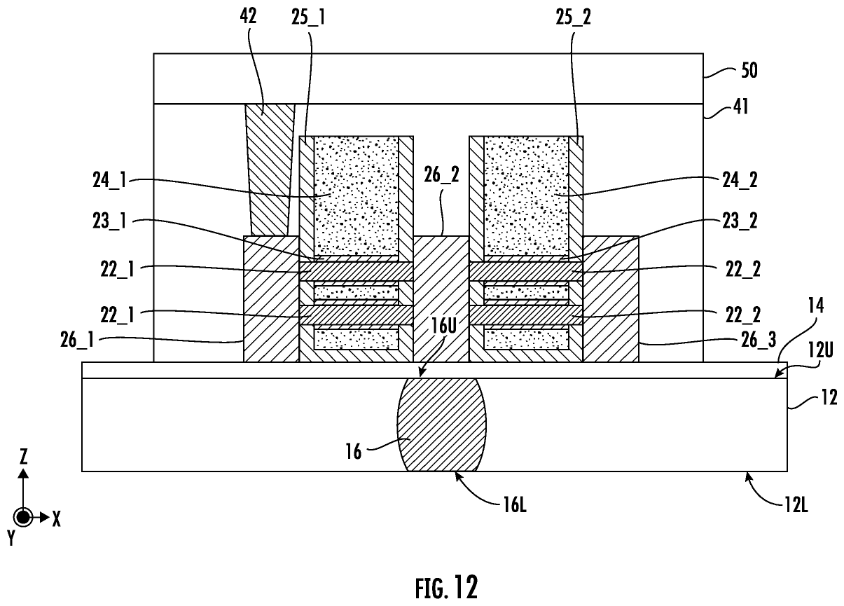

Referring to FIG. 12, the preliminary substrate 10 may be removed, and then the substrate 12 may be formed. The preliminary substrate 10 may be selectively removed such that the sacrificial layer 16 and the first interlayer 14 may not be removed. The sacrificial layer 16 may thus be provided in the substrate 12. The lower surface 16L of the sacrificial layer 16 may be coplanar with a lower surface 12L of the substrate 12, and an upper surface 12U of the substrate 12 may contact the first interlayer 14 (e.g., a lower surface of the first interlayer 14).

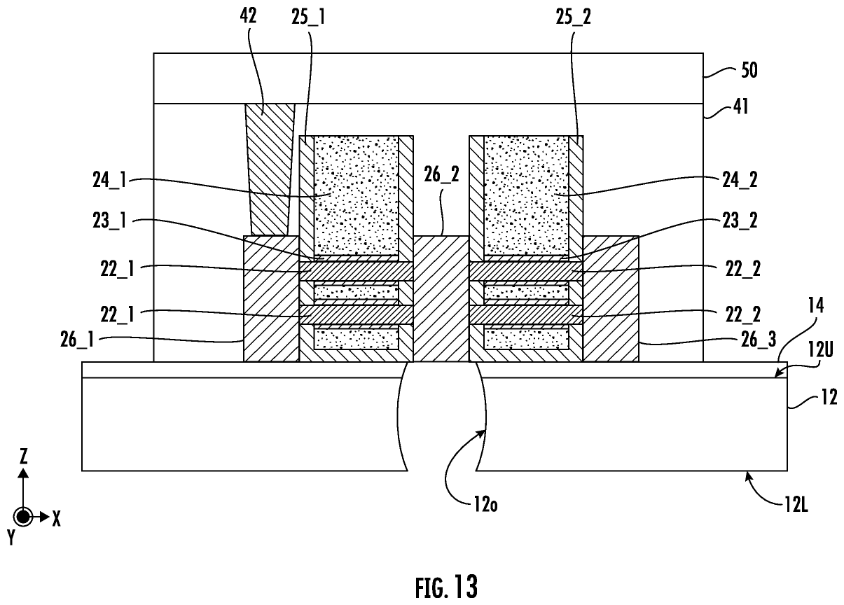

Referring to FIGS. 6, 13, 14 and 15, the sacrificial layer 16 may be replaced with a power contact 62 (Block 250). Referring to FIG. 13, the sacrificial layer 16 and a portion of the first interlayer 14 may be removed to form an opening 12o in the substrate 12 and the first interlayer 14. The opening 12o may expose the second source/drain region 26_2 (e.g., a lower surface of the second source/drain region 26_2). The sacrificial layer 16 and the portion of the first interlayer 14 may be removed by an etch process (e.g., a dry etch process and/or a wet etch process).

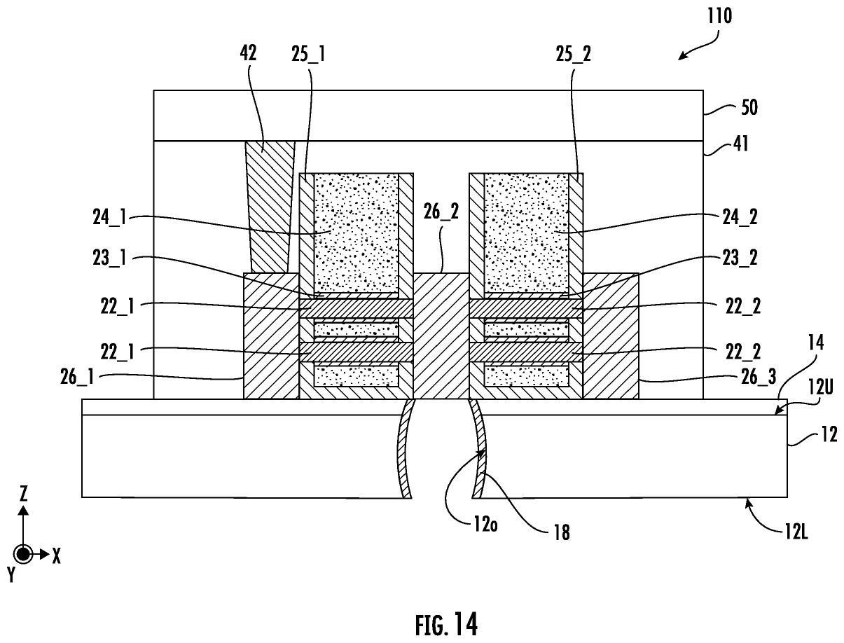

Referring to FIG. 14, a contact spacer 18 may be formed in the opening 12o. The contact spacer 18 may be formed by a deposition process (e.g., an atomic layer deposition (ALD) process and/or a chemical vapor deposition (CVD) process) and/or may be formed by a surface treatment process (e.g., a process adding nitrogen to a surface). In some embodiments, a lower surface of the contact spacer 18 may be coplanar with the lower surface 12L of the substrate 12, as illustrated in FIG. 14.

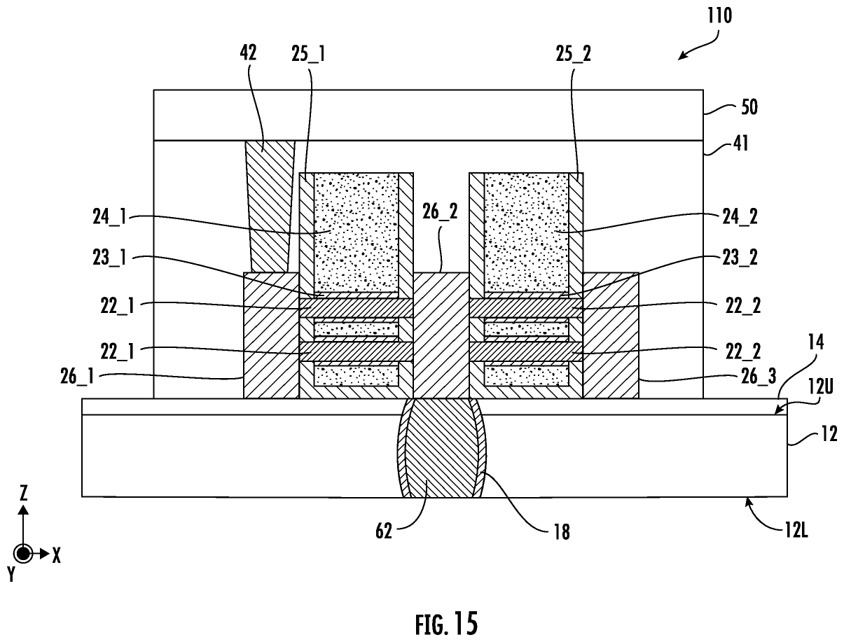

Referring to FIG. 15, the power contact 62 may be formed in the opening 12o after the contact spacer 18 is formed. The power contact 62 may contact the contact spacer 18. In some embodiments, the power contact 62 may include a flat upper surface contacting the second source/drain region 26_2.

Referring to FIGS. 1 and 6, a power rail 72 of a BSPDN structure 70 may be formed on the power contact 62 (e.g., a lower surface of the power contact 62) (Block 260).

In some embodiments, lower portions of the power contact 62 and the contact spacer 18 may be removed using process(es) (e.g., a grinding process, a wet etching process, a dry etching process and/or a Chemical Mechanical Polishing (CMP) process) before forming the power rail 72 such that the second integrated circuit device 120 illustrated in FIG. 2 may be formed.

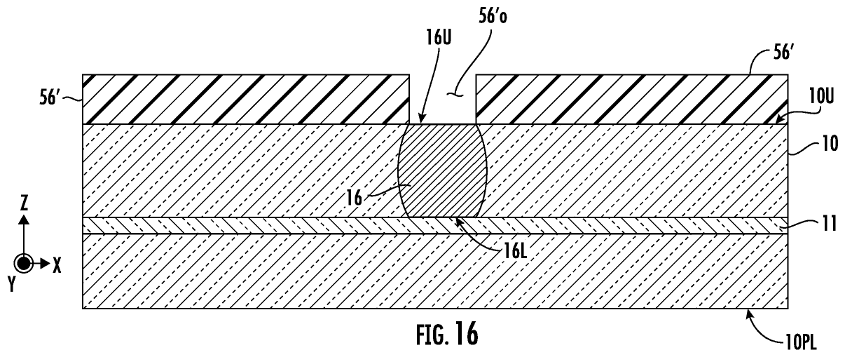

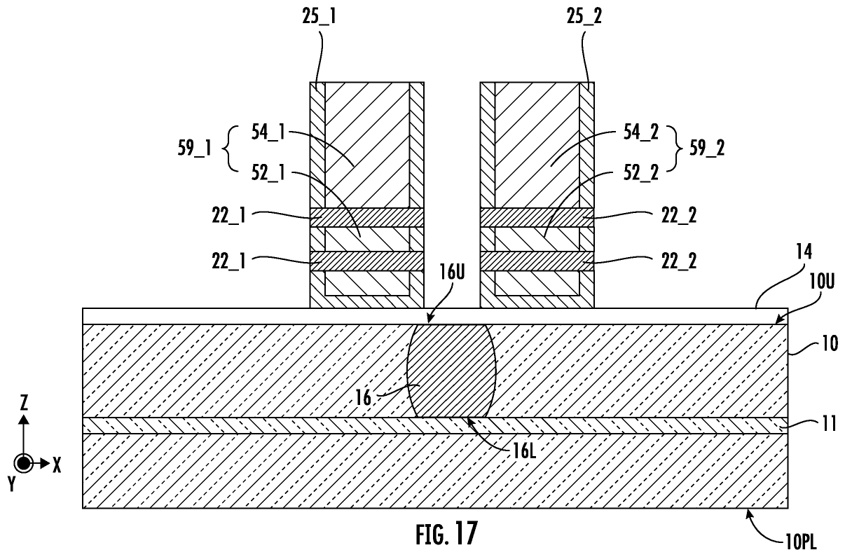

FIGS. 16 and 17 are cross-sectional views illustrating a method of forming an integrated circuit device according to some embodiments. Specifically, FIGS. 16 and 17 illustrate processes performed for Block 210 in FIG. 6.

Referring to FIG. 16, a mask layer 56′ may be formed on a preliminary substrate 10 (e.g., an upper surface 10U of the preliminary substrate 10). The mask layer 56′ may include a mask opening 56′o exposing a portion of the upper surface 10U of the preliminary substrate 10. An element (e.g., boron) may be added into a portion of the preliminary substrate 10 to convert that portion to a sacrificial layer 16 including the element. The element may be added by performing a process (e.g., an ion implantation process) on an upper surface 10U of the preliminary substrate 10 such that the element may be added into the portion of the preliminary substrate 10 through the upper surface 10U of the preliminary substrate 10. The process adding the element into the preliminary substrate 10 may be performed using the mask layer 56′ as a mask and may use boron atoms and/or a boron trifluoride (BF₃) gas. The mask layer 56′ may include an organic material (e.g., a photoresist) and/or an inorganic material (e.g., silicon oxynitride and/or a spin-on-glass material). In some embodiments, a first interlayer 14 may be formed between the preliminary substrate 10 and the mask layer 56′.

Referring to FIG. 17, the mask layer 56′ may be removed, and then the first interlayer 14 and first and second preliminary gate structures 59_1 and 59_2 may be formed on a preliminary substrate 10 (e.g., an upper surface 10U of the preliminary substrate 10). After then, processes described with reference to FIGS. 9 through 15 may be performed.

The sacrificial layer 16 may be formed in any position in the preliminary substrate 10 regardless of the position of first and second preliminary gate structures 59_1 and 59_2 when the sacrificial layer 16 is formed by the processes described with reference to FIGS. 16 and 17, and thus the sacrificial layer 16 may not be aligned with the first and second preliminary gate structures 59_1 and 59_2.

It will be understood that the third, fourth and fifth integrated circuit devices 130, 140 and 150 can be formed by methods similar to those described with reference to FIGS. 7-17 with appropriate modification to those methods.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity. Like reference numbers refer to like elements throughout.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing. Although an element is illustrated as a single layer in the drawings, that element may include multiple layers.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

What is claimed is:

1. A method of forming an integrated circuit device, the method comprising:
forming a sacrificial layer in a preliminary substrate by adding an element into the preliminary substrate;
forming a transistor structure on the preliminary substrate, wherein the transistor structure comprises a source/drain region;
replacing the sacrificial layer with a power contact that comprises an upper surface contacting the source/drain region; and
forming a power rail that contacts a lower surface of the power contact.

2. The method of claim 1, wherein the sacrificial layer is formed before forming the transistor structure.

3. The method of claim 1, wherein forming the transistor structure comprises:
forming a preliminary gate structure on the preliminary substrate;
forming the source/drain region that overlaps the sacrificial layer; and
replacing the preliminary gate structure with a gate structure,
wherein the sacrificial layer is formed after forming the preliminary gate structure.

4. The method of claim 3, wherein the element is added into the preliminary substrate by performing an ion implantation process.

5. The method of claim 1, wherein the preliminary substrate comprises an upper portion and a lower portion, and
forming the sacrificial layer comprises adding the element through an upper surface of the preliminary substrate, and the sacrificial layer is formed in the upper portion of the preliminary substrate, and
wherein replacing the sacrificial layer with the power contact comprises:
removing the lower portion of the preliminary substrate until the sacrificial layer is exposed;
replacing the upper portion of the preliminary substrate with a lower insulator;
removing the sacrificial layer, thereby forming an opening in the lower insulator; and
forming the power contact in the opening.

6. The method of claim 1, wherein forming the sacrificial layer comprises performing an ion implantation process on an upper surface of the preliminary substrate.

7. The method of claim 1, wherein the element comprises boron, and the preliminary substrate comprises silicon.

8. The method of claim 1, wherein the power contact comprises opposing side surfaces outwardly curved.

9. The method of claim 1, further comprising, before replacing the sacrificial layer with the power contact, forming a back-end-of-line (BEOL) structure including a conductive wire on the transistor structure.

10. A method of forming an integrated circuit device, the method comprising:
converting a portion of a preliminary substrate to a sacrificial layer including an element;
forming a transistor structure on the preliminary substrate, wherein the transistor structure comprises a source/drain region;
replacing the sacrificial layer with a power contact that comprises an upper surface contacting the source/drain region; and
forming a power rail that contacts a lower surface of the power contact.

11. The method of claim 10, wherein converting the portion of the preliminary substrate to the sacrificial layer comprises doping the portion of the preliminary substrate with the element through an upper surface of the preliminary substrate.

12. The method of claim 10, wherein forming the transistor structure comprises:
forming a preliminary gate structure on the preliminary substrate;
converting the portion of the preliminary substrate to the sacrificial layer by doping the portion of the preliminary substrate with the element using the preliminary gate structure as a mask;
forming the source/drain region that overlaps the sacrificial layer; and then
replacing the preliminary gate structure with a gate structure.

13. The method of claim 10, wherein the power contact comprises opposing side surfaces outwardly curved.

14. The method of claim 10, wherein the element comprises boron.

15. The method of claim 10, wherein converting the portion of the preliminary substrate to the sacrificial layer comprises adding the element through an upper surface of the preliminary substrate, the preliminary substrate comprises an upper portion and a lower portion, and the sacrificial layer is formed in the upper portion of the preliminary substrate, and
wherein replacing the sacrificial layer with the power contact comprises:
removing the lower portion of the preliminary substrate until the sacrificial layer is exposed;
replacing the upper portion of the preliminary substrate with a lower insulator, after removing the lower portion of the preliminary substrate;
removing the sacrificial layer, thereby forming an opening in the lower insulator; and
forming the power contact in the opening.

16. An integrated circuit device comprising:
a transistor structure on a substrate, wherein the transistor structure comprises a source/drain region;
a power rail that is spaced apart from the source/drain region in a first direction; and
a power contact,
wherein the source/drain region overlaps the power contact in the first direction, and the power contact is electrically connected to the source/drain region and the power rail, and
the power contact comprises opposing side surfaces outwardly curved.

17. The integrated circuit device of claim 16, wherein the power contact comprises an upper surface and a lower surface that is spaced apart from the upper surface in the first direction, and
the source/drain region contacts the upper surface of the power contact, and the power rail contacts the lower surface of the power contact.

18. The integrated circuit device of claim 17, further comprising a back-end-of-line (BEOL) structure including a conductive wire on the transistor structure,
wherein the transistor structure is between the BEOL structure and the power rail.

19. The integrated circuit device of claim 16, wherein the transistor structure further comprises a channel region, and
the channel region overlaps the power contact in the first direction.

20. The integrated circuit device of claim 16, wherein the substrate comprises a lower insulator, and the integrated circuit device further comprises a contact spacer,
the lower insulator and the contact spacer comprise different materials, and
the power contact is in the lower insulator, and the contact spacer contacts the opposing side surfaces of the power contact and separates the power contact from the lower insulator.
